(19) United States
(12) Patent Application Publication
(10) Pub. No.: US 2019/0377229 A1
(43) Pub. Date: Dec. 12, 2019

(54) DISPLAY DEVICE

(71) Applicant: Samsung Display Co., Ltd., Yongin-Si (KR)

(72) Inventors: Hee Kwang SONG, Suwon-si (KR); Ju Young YOON, Seoul (KR); Young Keun LEE, Suwon-si (KR)

(21) Appl. No.: 16/261,436

(22) Filed: Jan. 29, 2019

(30) Foreign Application Priority Data
Jun. 11, 2018 (KR) 10-2018-0067000

(51) Int. Cl. G02F 1/1335; F21V 8/00

(52) U.S. Cl. CPC G02F 1/133617; H01L 33/505; G02B 6/0053; G02B 6/005

(57) ABSTRACT

A backlight assembly includes an optical member that includes a light guide plate and a wavelength conversion layer disposed on the light guide plate; and a light source disposed on one side of the light guide plate. The wavelength conversion layer includes scattering particles having a particle size of 200 nm or less, and the scattering particles are of an anatase crystal type of titanium dioxide (TiO₂).

This application claims priority to Korean Patent Application No. 10-2018-0067000, filed on Jun. 11, 2018 in the Korean Intellectual Property Office, the disclosure of which is incorporated herein by reference in its entirety.

### BACKGROUND

### 1. Field of the Invention

The present disclosure relates to a display device.

### 2. Description of the Related Art

A liquid crystal display (LCD) device receives light from a backlight assembly and displays an image by controlling emission of the light received from the backlight assembly. Some backlight assemblies include a light source and a light guide plate. The light guide plate receives light from the light source and guides the traveling direction of the light toward a display panel of the LCD device. In some LCD devices, the light source emits white light, and the emitted white light is filtered by a color filter of the display panel to realize a color.

Recently, there have been introduced many techniques for realizing white light using a blue light-emitting diode (LED) as a light source and quantum dots (QDs) that absorbs the blue light and emits red light and green light. The white light that is realized using the blue LED and the quantum dots can have high luminance and excellent color reproducibility. Nevertheless, when these techniques are applied to an LED backlight assembly, there is a need for reducing light loss and improving color uniformity.

### SUMMARY

Aspects of the present disclosure provide a backlight assembly, a display device, and an optical member, each of which can be used for light guiding and wavelength conversion as an integrated single member. In particular, the integrated single member is optimized for efficiently extracting light from a near ultraviolet (nUV) light source.

However, aspects of the present disclosure are not restricted to the exemplary embodiments set forth herein. The above and other aspects of the present disclosure will become more apparent to one of ordinary skill in the art to which the present disclosure pertains by referencing the detailed description of the present disclosure given below.

According to an aspect of the present disclosure, a backlight assembly includes an optical member including a light guide plate and a wavelength conversion layer that is disposed on the light guide plate; and a light source disposed on one side of the light guide plate. The wavelength conversion layer includes scattering particles having a particle size of 200 nm or less, and the scattering particles are of an anatase crystal type of titanium dioxide (TiO₂).

In an exemplary embodiment, the light source may provide first light of a first wavelength to the light guide plate, and the light conversion layer may include first wavelength conversion particles that convert the first light of the first wavelength to light of a second wavelength and second wavelength conversion particles that convert the first light of the first wavelength to light of a third wavelength.

In an exemplary embodiment, the light source may provide second light of a fourth wavelength that is different from the first wavelength to the light guide plate, the first wavelength conversion particles may convert the second light to the light of the second wavelength, and the second wavelength conversion particles may convert the second light to the light of the third wavelength.

In an exemplary embodiment, the first wavelength and the fourth wavelength may be within a wavelength range of blue light or near ultraviolet light.

In an exemplary embodiment, the first wavelength may be 320 nm to 420 nm, and the fourth wavelength may be 420 nm to 470 nm.

In an exemplary embodiment, the light source may include a light emitting element that emits the first light and third wavelength conversion particles that convert the first light of the first wavelength to the second light of the fourth wavelength.

In an exemplary embodiment, the second wavelength may be within a wavelength range of green light, and the third wavelength may be within a wavelength range of red light.

In an exemplary embodiment, the first wavelength conversion particles may include quantum dots, and the second wavelength conversion particles may include a KSF fluorescent material.

In an exemplary embodiment, the wavelength conversion layer may further include third wavelength conversion particles that convert the first light to second light of a fourth wavelength.

In an exemplary embodiment, the first wavelength conversion particles may convert the second light of the fourth wavelength to the light of the second wavelength, and the second wavelength conversion particles may convert the second light of the fourth wavelength to the light of the third wavelength.

In an exemplary embodiment, a volumetric ratio of the scattering particles in the wavelength conversion layer may be less than 5%.

In an exemplary embodiment, a reflectance of the scattering particles to light of a wavelength of 400 nm may be 80% or more.

In an exemplary embodiment, the optical member may further include a low refractive layer disposed between the light guide plate and the wavelength conversion layer, and the light guide plate, the low refractive layer, and the wavelength conversion layer may be integrally coupled with each other.

In an exemplary embodiment, the backlight assembly may further include a passivation layer covering the wavelength conversion layer and the low refractive layer.

In an exemplary embodiment, the light guide plate may include glass.

According to an aspect of the present disclosure, a display device includes a backlight assembly including an optical member that includes a light guide plate and a wavelength conversion layer that is disposed on the light guide plate, and a light source disposed on one side of the light guide plate; and a display panel disposed over the backlight assembly. The wavelength conversion layer includes scattering particles having a particle size of 200 nm or less, and the scattering particles are of an anatase crystal type of titanium dioxide (TiO₂).

In an exemplary embodiment, the light source may provide first light of a first wavelength to the light guide plate, and the light conversion layer may include first wavelength conversion particles that convert the first light of the first wavelength to light of a second wavelength and second wavelength conversion particles that convert the first light of the first wavelength to light of a third wavelength.

According to an aspect of the present disclosure, an optical member includes first wavelength conversion particles that convert first light of a first wavelength to light of a second wavelength; second wavelength conversion particles that convert the first light of the first wavelength to light of a third wavelength; and a wavelength conversion layer including scattering particles having a particle size of 200 nm or less. The scattering particles are of an anatase crystal type of titanium dioxide (TiO₂).

In an exemplary embodiment, the optical member may further include a low refractive layer disposed under the wavelength conversion layer; and a light guide plate disposed under the low refractive layer and including glass, wherein the light guide plate, the low refractive layer, and the wavelength conversion layer are integrally coupled with each other.

In an exemplary embodiment, the wavelength conversion layer may further include third wavelength conversion particles that convert the first light of the first wavelength to second light of a fourth wavelength, and the first wavelength conversion particles may convert the second light of the fourth wavelength to the light of the second wavelength, and the second wavelength conversion particles may convert the second light of the fourth wavelength to the light of the third wavelength.

### BRIEF DESCRIPTION OF THE DRAWINGS

The above and other aspects and features of the present disclosure will become more apparent to those of ordinary skill in the art by describing in detail exemplary embodiments thereof with reference to the accompanying drawings, in which:

FIG. 1 is a perspective view of an optical member and a light source according to an embodiment;

FIG. 2 is a cross-sectional view of an optical member taken along line II-IT of FIG. 1;

FIG. 3 is a cross-sectional view of an optical member according to another embodiment;

FIGS. 4 and 5 are cross-sectional views of low refractive layers according to various embodiments;

FIG. 6 is a cross-sectional view of the light source of FIG. 1;

FIG. 7 is a cross-sectional view of the wavelength conversion layer of FIG. 1;

FIGS. 8A and 8B are enlarged views of the wavelength conversion particles of FIG. 7;

FIG. 9 is an enlarged view of a scattering particle of FIG. 7;

FIG. 10 is a graph showing the light absorption rates of second wavelength conversion particles and third wavelength conversion particles with respect to a wavelength;

FIG. 11 is a graph showing light scattering rates of two different kinds of scattering particles with respect to a wavelength;

FIG. 12 is a graph showing light scattering rates of scattering particles with respect to a particle size;

FIG. 13 is a graph showing intensity of green light and red light with respect to a light source of an optical member that includes scattering particles according to an embodiment;

FIG. 14 is a perspective view of an optical member and a light source according to another embodiment;

FIG. 15 is a cross-sectional view of the optical member of FIG. 14;

FIG. 16 is a cross-sectional view of the light source of FIG. 14;

FIG. 17 is a cross-sectional view of a wavelength conversion layer included in the optical member of FIG. 15;

FIG. 18 is an exploded perspective view of a display device including a modified light guide plate according to another embodiment;

FIG. 19 is a cross-sectional view of the display device of FIG. 18;

FIG. 20 is an exploded perspective view of a display device according to another embodiment;

FIG. 21 is a cross-sectional view of the display device of FIG. 20;

FIG. 22 is an exploded perspective view of a display device according to still another embodiment; and

FIG. 23 is a cross-sectional view of the display device of FIG. 22.

### DETAILED DESCRIPTION OF THE EMBODIMENTS

The advantages and features of the present disclosure for achieving the same will be apparent to those of ordinary skill in the art by referring to the embodiments to be described in detail with reference to the accompanying drawings. However, the present disclosure is not limited to the embodiments disclosed hereinafter, but can be implemented in diverse forms. The subject matters defined in the description, such as the detailed construction and elements, are nothing but specific details provided to assist those of ordinary skill in the art in a comprehensive understanding of the present disclosure.

Where an element is described as being related to another element such as being “on” another element or “located on” a different layer or layers, it includes both a case where an element is located directly on another element or a layer and another case where an element is located on another element via another layer or element. In contrast, where an element is described as being related to another element such as being “directly on” another element or “located directly on” a different layer or layers, it indicates a case where an element is located on another element or a layer with no intervening element or layer therebetween. Throughout the specification, the same reference numerals are used for the same or similar parts.

Hereinafter, embodiments of the present disclosure will be described with reference to the accompanying drawings.

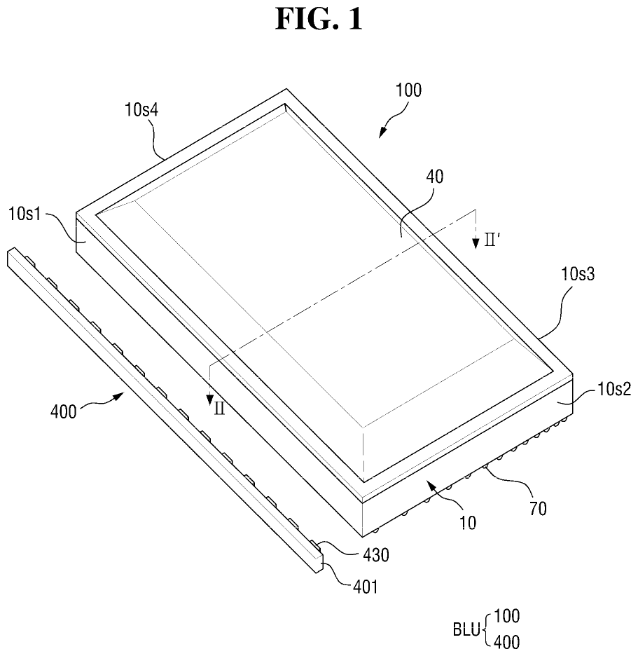

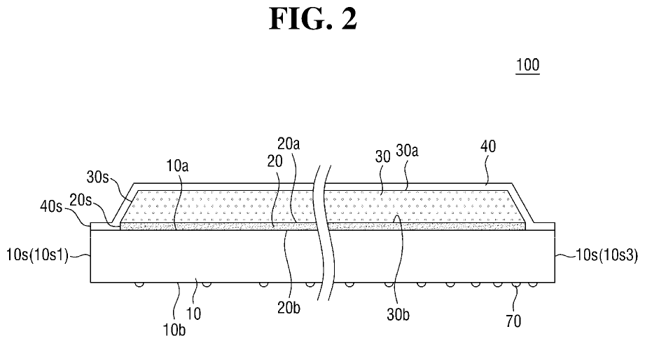

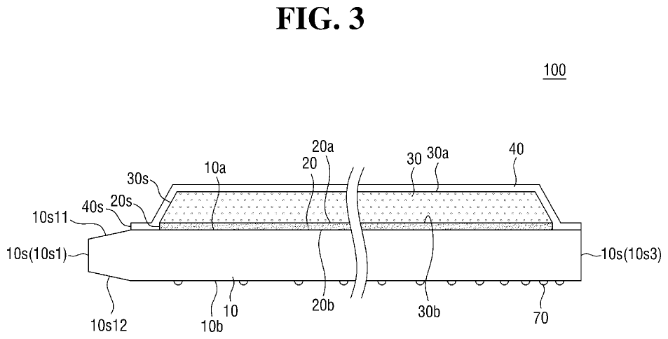

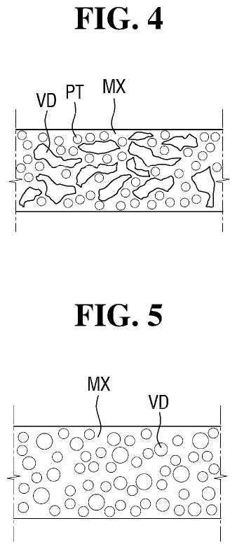

FIG. 1 is a perspective view of a backlight assembly according to an embodiment. FIG. 2 is a cross-sectional view of an optical member taken along line II-IT of FIG. 1. FIG. 3 is a cross-sectional view of an optical member according to another embodiment. FIGS. 4 and 5 are cross-sectional views of low refractive layers according to various embodiments.

Referring to FIGS. 1 to 5, a backlight assembly includes a light source 400 and an optical member 100. The light source 400 may be disposed on one side of the optical member 100. The optical member 100 may receive light emitted from the light source 400 and convert or control a light path and/or a wavelength of the light.

In an application example of the backlight assembly, the light source 400 may include a printed circuit board 401 and a plurality of LEDs 430 mounted on the printed circuit board 401. The light source 400 may be disposed adjacent to at least one side surface 10s of a light guide plate 10 of the optical member 100. Further, the plurality of LEDs 430 included in the light source 400 may be disposed adjacent to the at least one side surface 10s of the light guide plate 10. The light guide plate 10 may have a rectangular shape having two long sides and two short sides. Although it is shown in the drawings that the plurality of LEDs 430 are disposed on a side surface 10s1 of one long side of the light guide plate 10, the present disclosure is not limited thereto. For example, the plurality of LEDs 430 may be disposed adjacent to the side surface 10s1 and its opposite side surface 10s3 of the two long sides of the light guide plate 10, or may be disposed adjacent to a side surface 10s2 or 10s4 of one short side of the light guide plate 10 or the side surfaces 10s2 and 10s4 of both short sides of the light guide plate 10. In the embodiment of FIG. 1, the side surface 10s1 of one long side of the light guide plate 10 that is adjacent to the LEDs 430 is referred to a light incidence surface (for convenience of explanation, represented by ‘10s1’ in the drawings), and the side surface 10s3 of the other long side of the light guide plate 10 that is opposite to the side surface 10s1 is also referred to as a light counter surface (for convenience of explanation, represented by ‘10s3’ in the drawings).

In an embodiment, as shown in FIG. 1, each of the plurality of LED 430 may be a top-emission type LED that emits light to a top surface. However, the present disclosure is not limited thereto, and each of the plurality of LED 430 may be a side-emission type LED that emits light to a side surface.

Details of the structure and light emission principle of the light source 400 will be described later with reference to FIG. 3.

In addition to the light guide plate 10, the optical member 100 further includes a low refractive layer 20 disposed on the light guide plate 10, a wavelength conversion layer 30 disposed on the low refractive layer 20, and a passivation layer 40 disposed on the wavelength conversion layer 30. The light guide plate 10, the low refractive layer 20, the wavelength conversion layer 30, and the passivation layer 40 may be integrally coupled to each other.

The light guide plate 10 serves to guide a traveling path of light emitted from the light source 400. The light source 400 is disposed on one side of the light guide plate 10.

The light guide plate 10 may have a substantially polygonal columnar shape. For example, the planar shape of the light guide plate 10 may be rectangular, but is not limited thereto. In the exemplary embodiment shown in FIG. 2, the light guide plate 10 has a rectangular planar shape with a uniform thickness including an upper surface 10a, a lower surface 10b, and four side surfaces 10s including 10s1, 10s2, 10s3, and 10s4.

In an embodiment, each of the upper surface 10a and lower surface 10b of the light guide plate 10 is located on a plane. The plane on which the upper surface 10a is located and the plane on which the lower surface 10b is located may be substantially parallel to each other, so that the light guide plate 10 may have a uniform thickness.

In some embodiments, the light guide plate 10 may include inclined edge surfaces between the upper surface 10a and one or more of the side surfaces 10s and/or between the lower surface 10b and one or more of the side surfaces 10s. In the embodiment shown in FIG. 3, the light guide plate 10 includes a first edge surface 10s11 that extends from an upper side of the side surface 10s1 toward the upper surface 10a (e.g., a light incidence surface) and is inclined upwardly in the thickness direction, and a second edge surface 10s12 that extends from a lower side of the side surface 10s1 toward the lower surface 10b and is inclined downwardly in the thickness direction. Therefore, the thickness of the light guide plate 10 increases from the side surface 10s1 toward the side surface 10s3 that faces the one side surface 10s1, and the upper surface 10a and the lower surface 10b have a flat shape, so that the light guide plate 10 may have a uniform thickness except the in a region corresponding to the inclined edge surfaces 10s11 and 10s12. Generally, the inclined edge surfaces 10s11 and 10s12 may be referred to as chamfer surfaces (e.g., a first chamfer surface 10s11 and a second chamfer surface 10s12). However, the present disclosure is not limited thereto, and the light guide plate 10 may have only one of the first edge surface 10s11 (or the first chamfer surface) and the second edge surface 10s12 (or the second chamfer surface). The aforementioned first edge surface 10s11 and second edge surface 10s12 serve to efficiently emit the light staying at the peripheral portion (e.g., on the side surface 10s1) toward the outside (e.g., the wavelength conversion layer 30) of the light guide plate 10.

Hereinafter, the embodiment in which the upper surface 10a and the side surface 10s directly meet each other without the edge surfaces 10s11 and 10s12 and have an angle of 90° therebetween (e.g., the optical member 100 illustrated in FIG. 2) will be described.

A scattering pattern 70 may be disposed on the lower surface 10b of the light guide plate 10. The scattering pattern 70 serves to change a traveling path and/or a reflection angle of light proceeding in the light guide plate 10 by total reflection and to emit the light to the outside of the light guide plate 10.

In an embodiment, the scattering pattern 70 may be provided in a separate layer or pattern. For example, the scattering pattern 70 may be provided by forming a pattern layer including a convex pattern, or a concave pattern on the lower surface 10b of the light guide plate 10, or by forming a printed pattern thereon. Although FIG. 2 shows that the scattering pattern 70 is formed in a convex pattern having a uniform shape, the present disclosure is not limited thereto. For example, the scattering pattern 70 may include a convex pattern and a concave pattern, and may also include a convex pattern and a pattern having concave grooves in a part of the region of a convex pattern (e.g., a central region).

In another embodiment, the scattering pattern 70 may correspond to a surface of the light guide plate 10 itself instead of being formed or provided on the lower surface 10b of the light guide plate 10. For example, concave grooves may be formed in the lower surface 10b of the light guide plate 10 to function as the scattering pattern 70.

The arrangement density of the scattering pattern 70 may differ with respect to a region of the light guide plate 10. For example, the arrangement density of the scattering pattern 70 may be lower in a region adjacent to the light incidence surface 10s1 that has a relatively large amount of light than in a region adjacent to the light counter surface 10s3 that has a relatively small amount of light.

The light guide plate 10 may include an inorganic material or an organic material. For example, the light guide plate 10 may be made of glass, but the present disclosure is not limited thereto.

The low refractive layer 20 may be disposed on the upper surface 10a of the light guide plate 10. The low refractive layer 20 may be formed directly on the upper surface 10a of the light guide plate 10 to be in contact with the upper surface 10a of the light guide plate 10. The low refractive layer 20 is interposed between the light guide plate 10 and the wavelength conversion layer 30 to achieve total reflection of the light guide plate 10.

The difference between the refractive index of the light guide plate 10 and the refractive index of the low refractive layer 20 may be 0.2 or more. When the refractive index of the low refractive layer 20 is lower than the refractive index of the light guide plate 10 by 0.2 or more, sufficient total reflection may be obtained through the upper surface 10a of the light guide plate 10. The upper limit of the difference between the refractive index of the light guide plate 10 and the refractive index of the low refractive layer 20 may not be limited to a specific number, but may be 1 or less in consideration of the material of the light guide plate 10 and the refractive index of the low refractive layer 20.

The refractive index of the low refractive layer 20 may be in the range of 1.2 to 1.4. When the refractive index of the low refractive layer 20 is 1.2 or higher, an increase in the manufacturing cost can be suppressed, and when the refractive index of the low refractive layer 20 is 1.4 or less, the total reflection critical angle on the upper surface 10a of the light guide plate 10 can be made sufficiently small. In an exemplary embodiment, the low refraction layer 20 has a refractive index of about 1.25.

The low refractive layer 20 may include voids to exhibit the above-mentioned low refractive index. The voids may be formed of vacuum, or may be filled with a void layer including air, gas, or the like. The voids may be defined by particles, matrices, and so on. For a more detailed description, reference is made to FIGS. 4 and 5.

In an embodiment, as shown in FIG. 4, the low refractive layer 20 may include a plurality of particles PT, a matrix MX surrounding the particles PT, and a plurality of voids VD. The particles PT may be filler for adjusting the refractive index and the mechanical strength of the low refractive layer 20.

In the low refractive layer 20, the particles PT are dispersed, the matrix MX is partially widened, and the voids VD are formed at the corresponding sites. For example, when the particles PT and the matrix MX are mixed with a solvent and then dried and/or cured, the solvent evaporates, and in this case, the voids VD may formed in the matrix MX.

In another embodiment, as shown in FIG. 5, the low refractive layer 20 may include a matrix MX and a plurality of voids VD without particles PT. For example, the low refractive layer 20 may include one connected matrix MX such as a foam resin and the plurality of voids VD disposed therein.

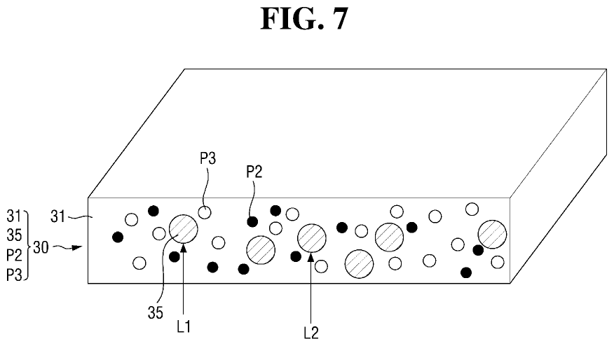

The wavelength conversion layer 30 is disposed on the low refractive layer 20. The wavelength conversion layer 30 serves to convert at least a part of light incident on the wavelength conversion layer 30. Referring to FIG. 7, the wavelength conversion layer 30 includes a second binder layer 31, second and third wavelength conversion particles P2 and P3, and scattering particles 35. Details of the second and third wavelength conversion particles P2 and P3 and the scattering particles 35 will follow.

In one embodiment, the wavelength conversion layer 30 may be thicker than the low refractive layer 20. The thickness of the wavelength conversion layer 30 may be about 10 μm to 50 μm. In an exemplary embodiment, the thickness of the wavelength conversion layer 30 may be about 15 μm.

The wavelength conversion layer 30 may cover an upper surface 20a of the low refractive layer 20 and entirely overlap the low refractive layer 20. A lower surface 30b of the wavelength conversion layer 30 may be in direct contact with the upper surface 20a of the low refractive layer 20. In an embodiment, a side surface 30s of the wavelength conversion layer 30 may be aligned with a side surface 20s of the low refractive layer 20. The inclination angle of the side surface 30s of the wavelength conversion layer 30 may be smaller than the inclination angle of the side surface 20s of the low refractive layer 20. As will be described later, when the wavelength conversion layer 30 is formed by a process such as slit coating, the side surface 30s of the wavelength conversion layer 30 may be relatively thicker to have a gentle inclination angle than the side surface 20s of the low refractive layer 20. However, the present disclosure is not limited thereto. The inclination angle of the side surface 30s of the wavelength conversion layer 30 may be substantially equal to or smaller than the inclination angle of the side surface 20s of the low refractive layer 20.

The wavelength conversion layer 30 may be formed by a process such as coating. For example, the wavelength conversion layer 30 may be formed by applying a wavelength conversion composition onto the low refractive layer 20 by applying slit coating, drying, and curing the wavelength conversion composition. However, the present disclosure is not limited thereto, and various materials and manufacturing processes may be used.

The passivation layer 40 is disposed on the low refractive layer 20 and the wavelength conversion layer 30. The passivation layer 40 serves to prevent penetration of moisture and/or oxygen (hereinafter referred to as ‘moisture/oxygen’). The passivation layer 40 may include an inorganic material. For example, the passivation layer 40 may be made of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride, or may be formed of a metal thin film having light transmittance. In an exemplary embodiment, the passivation layer 40 may be made of silicon nitride.

The passivation layer 40 may entirely cover the low refractive layer 20 and the wavelength conversion layer 30 including at least one side surface thereof. In an exemplary embodiment, the passivation layer 40 may entirely cover the low refractive layer 20 and the wavelength conversion layer 30 at all side surfaces thereof, but the present disclosure is not limited thereto.

The passivation layer 40 may entirely overlap the wavelength conversion layer 30, cover an upper surface 30a of the wavelength conversion layer 30, and further extend outwardly therefrom to cover the side surface 30s of the wavelength conversion layer 30 and the side surface 20s of the low refractive layer 20. The passivation layer 40 may be in contact with the upper surface 30a and the side surface 30s of the wavelength conversion layer 30 and the side surface 20s of the low refractive layer 20. The passivation layer 40 may extend to the upper surface 10a of the light guide plate 10 that is exposed by the low refractive layer 20 to allow a part of the edge of the passivation layer 40 to be in direct contact with the upper surface 10a of the light guide plate 10. In an embodiment, a side surface 40s of the passivation layer 40 may be aligned with the side surface 10s of the light guide plate 10. The inclination angle of the side surface 40s of the passivation layer 40 may be larger than the inclination angle of the side surface 30s of the wavelength conversion layer 30. Moreover, the inclination angle of the side surface 40s of the passivation layer 40 may be larger than the inclination angle of the side surface 20s of the low refractive layer 20. However, when the light guide plate 10 includes the chamfer surfaces 10s11 and 10s12 described above with respect to FIG. 3, the side surface 10s1 of the light guide plate 10 may extend outwardly from the side surface 40s of the passivation layer 40 (a side surface adjacent to the side surface 10s1 of the light guide plate 10) to have a protruding structure.

Hereinafter, the aforementioned light source 400 and the wavelength conversion layer 30 will be described in detail.

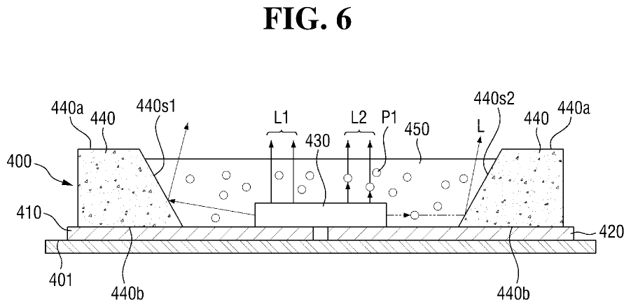

FIG. 6 is a cross-sectional view of the light source 400 of FIG. 1.

The light source 400 may include a printed circuit board 401, a first electrode 410, a second electrode 420, an LED 430, a partition wall 440, and a first binder layer 450. The printed circuit board 401 supports a plurality of elements of the light source 400 including the LED 430. The printed circuit board 401 may be an insulating substrate made of an inorganic material.

The light source 400 may emit light (e.g., first wavelength light L1 and second wavelength light L2) toward the light guide plate 10.

The first electrode 410 may be disposed on the printed circuit board 401, and may be spaced apart from the second electrode 420. The first electrode 410 and the second electrode 420 include a conductive material, and serve to form a forward or reverse current flowing through the LED 430. The first electrode 410 may be an anode electrode, and the second electrode 420 may be a cathode electrode. However, the present disclosure is not limited thereto, and the first electrode 410 may be a cathode electrode, and the second electrode 420 may be an anode electrode. The space between the first electrode 410 and the second electrode 420 may be an empty space. However, although not shown, the same material that is used to form the partition wall 440 may be interposed between the first electrode 410 and the second electrode 420. As will be described later, the partition wall 440 may include an insulating material to prevent unexpected indirect electrical contact between the first electrode 410 and the second electrode 420.

The LED 430 is disposed on the first electrode 410 and the second electrode 420, and is simultaneously in contact with the first electrode 410 and the second electrode 420 to recombine holes and electrons to generate light. That is, the holes and the electrons are recombined in the LED 430 to generate excitons, and the excitons change from a ground state to an excited state and emit the light corresponding to a bandgap between the ground state and the excited state.

The LED 430 may emit the first wavelength light L1. In an embodiment, the first wavelength light L1 may have a first wavelength λ1. The first wavelength light L1 may be light having a wavelength band of approximately 320 nm to 420 nm. Generally, the wavelength band of the first wavelength light L1 may have an ultraviolet wavelength band (320 nm to 400 nm) that is adjacent to a visible light wavelength band (400 nm to 420 nm).

The partition wall 440 may be disposed around the LED 430. Specifically, the partition wall 440 may be disposed on the first electrode 410 and the second electrode 420, and may be spaced apart from the LED 430. Although not shown in the drawing, the partition wall 440 may be an integral structure surrounding the LED 430.

The partition wall 440 reflects the first wavelength light L1 emitted from the LED 430 or the second wavelength light L2 to be described later toward the light guide plate 10. The partition wall 440 may be formed of a plastic resin having high reflectance to effectively reflect the light toward the light guide plate 10. The reflectance of the plastic resin may be approximately 80% or more. That is, in an embodiment, the reflectance of the partition wall 440 may be about 80% or more, and the absorption rate thereof may be about 20% or less. The partition wall 440 may be formed of an insulating material to protect the light source 400.

Side surfaces 440s1 and 440s2 of the partition wall 440 may have an inclined surface to effectively reflect the light emitted from the light source 400 toward the light guide plate 10. In one embodiment, the thickness of the partition wall 440 may be greater than the thickness of the first binder layer 450. However, the present disclosure is not limited thereto, and the thickness of the partition wall 440 may be substantially equal to the thickness of the first binder layer 450.

The first binder layer 450 may be disposed between the adjacent partition walls 440. The first binder layer 450 may be in contact with the side surface 440s1 or 440s2 of the partition wall 440. The first binder layer 450 may be disposed on the first electrode 410 and the second electrode 420 and surround the upper surface and side surfaces of the LED 430. The first binder layer 450 may serve as a medium in which the wavelength conversion particles (e.g., first wavelength conversion particles) are dispersed, and may be made of various resin compositions generally referred to as a binder.

The first binder layer 450 may include a plurality of first wavelength conversion particles P1. The first wavelength conversion particle P1 may convert incident light (e.g., the first wavelength light L1) having the first wavelength λ1 to light having the second wavelength λ2. The second wavelength λ2 may be longer than the first wavelength λ1. In an embodiment, the wavelength band of the second wavelength λ2 may be approximately 420 nm to 470 nm (typically blue wavelength). In an embodiment, the first wavelength conversion particle P1 may absorb incident light having a wavelength (e.g., the first wavelength λ1) that is shorter than the wavelength band of the second wavelength light L2, and emit light having a wavelength of a specific wavelength band (e.g., a blue wavelength band (420 nm to 470 nm).

The first wavelength conversion particle P1 may include at least one of a phosphor or a fluorescent material. For example, the first wavelength conversion particle P1 may include a fluorescent material. Examples of the fluorescent material may include 4,4′-bis(9-ethyl-3-carbazovinylene)-1,1′-biphenyl (BczVBi), distyrylarylene (DSA), distyrylarylene derivatives, distyrylbenzene (DSB), distyrylbenzene derivatives, DPVBi (4,4′-bis (2,2′-diphenylvinyl) 1,1′-biphenyl), DPVBi derivatives, spiro-DPVBi, and spiro-6P.

In an embodiment, the residual first wavelength light L1 that is not absorbed by the first wavelength conversion particle P1 may be directly emitted toward the light guide plate 10 without being incident on the first wavelength conversion particle P1. Accordingly, the light having passed through the light source 400 may include the first wavelength light L1 and the second wavelength light L2. As will be described later with reference to FIG. 7, when the first wavelength light L1 is used as the light emitted from the LED 430, the light absorption of the second and third wavelength conversion particles P2 and P3 (e.g., green and red wavelength conversion particles) may increase, and thus the intensity of the third wavelength light (e.g., green light) and the intensity of the fourth wavelength light (e.g., red light) may increase.

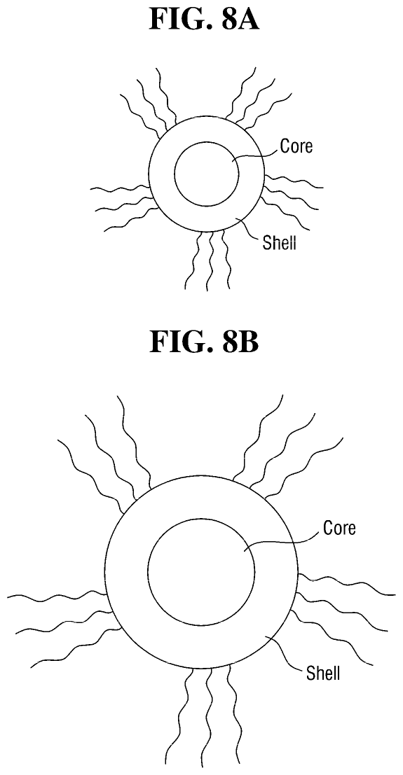

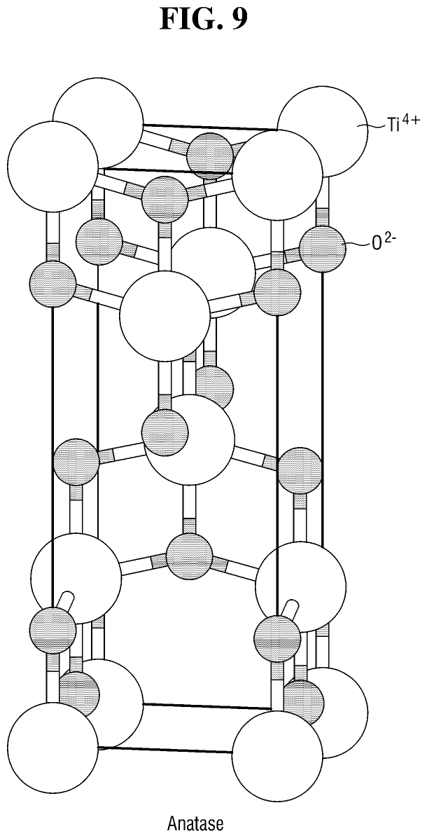

FIG. 7 is a cross-sectional view of the wavelength conversion layer 30 of FIG. 1, FIGS. 8A and 8B are enlarged views of the second wavelength conversion particle P2 and the third wavelength particle P3 of FIG. 7, respectively, and FIG. 9 is a structural view of a scattering particle 35.

Referring to FIGS. 7 to 9, the wavelength conversion layer 30 converts the wavelength of at least a part of incident light. The wavelength conversion layer 30 may include a second binder layer 31 and a plurality of wavelength conversion particles including second wavelength conversion particles P2 and third wavelength conversion particles P3 that are dispersed in the second binder layer 31. The wavelength conversion layer 30 may further include the scattering particles 35 dispersed in the second binder layer 31. The second wavelength conversion particle P2 is a particle that absorbs light having a specific wavelength (e.g., a wavelength shorter than a third wavelength λ3) and converts the light to a third wavelength light L3 having the third wavelength λ3, and the third wavelength conversion particle P3 is a particle that absorbs light having a specific wavelength (e.g., a wavelength shorter than a fourth wavelength λ4) and converts the light to a fourth wavelength light L4 having the fourth wavelength λ4. As will be described later, with respect to the constituent materials of the second and third wavelength conversion particles P2 and P3, the wavelength band to be absorbed may be different. In an embodiment, the third wavelength λ3 of the third wavelength light L3 may correspond to a wavelength band (usually green light) of approximately 520 nm to 570 nm. The fourth wavelength λ4 of the fourth wavelength light L4 may correspond to a wavelength band (usually red light) of approximately 620 nm to 670 nm. It should be understood that the blue, green, and red wavelengths are not limited to the above examples and include all wavelength ranges that can be recognized in the art as blue, green, and red wavelengths.

The second binder layer 31 is a medium in which the second and third wavelength converting particles P2 and P3 are dispersed, and may have substantially the same function and configuration as the above-described first binder layer 450 of the light source 400.

Each of the second and third wavelength converting particles P2 and P3 may be a quantum dot (QD) or may be made of a fluorescent material. In an embodiment, the quantum dot (QD) is a material having a crystal structure of several nanometers in size and including several hundreds to several thousands of atoms, and exhibit a quantum confinement effect of an energy bandgap increasing due to its small size. When light of a wavelength having higher energy than the energy bandgap is incident on the quantum dot, the quantum dot absorbs the light to be excited and emits light of a specific wavelength to fall to a ground state. The emitted light may have a wavelength corresponding to the energy bandgap. The quantum dots included in the wavelength conversion layer 30 can control the luminescent characteristics due to the quantum confinement effect by adjusting the size and composition thereof.

The quantum dot (QD) may include, for example, at least one of II-VI group compounds, II-V group compounds, III-VI group compounds, III-V group compounds, IV-VI group compounds, I-III-VI group compounds, II-IV-VI group compounds, and II-IV-V group compounds.

The quantum dot (QD) may include a core and a shell overcoating the core. The core may include, but is not limited to, at last one of CdS, CdSe, CdTe, ZnS, ZnSe, ZnTe, GaN, GaP, GaAs, GaSb, AlN, AlP, AlAs, AlSb, InP, InAs, InSb, SiC, Ca, Se, In, P, Fe, Pt, Ni, Co, Al, Ag, Au, Cu, FePt, Fe₂O₃, Fe₃O₄, Si, and Ge. The shell may include, but is not limited to, at least one of ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbS, PbSe, and PbTe. When the second and third wavelength converting particles P2 and P3 are the quantum dots (QD), the second wavelength conversion particle P2 may convert light of a wavelength shorter than the second wavelength λ2 to light of the second wavelength λ2 and emit the converted light. The third wavelength conversion particle P3 may convert light of a wavelength shorter than the third wavelength λ3 to light of the third wavelength λ3 and emit the converted light.

In an embodiment, the wavelength conversion layer 30 may include the second wavelength conversion particles P2 converting a light (e.g., the first wavelength light L1 of about 320 nm to 420 nm and the second wavelength light L2 of about 420 nm to 470 nm) having a wavelength shorter than the wavelength λ3 (e.g., 520 nm to 570 nm) of the third wavelength light L3 to the third wavelength light L3, and third wavelength conversion particles P3 converting a light (e.g., the first wavelength light L1, the second wavelength light L2, and the third wavelength light L3) having a wavelength shorter than the wavelength λ4 (e.g., 620 nm to 670 nm) of the fourth wavelength light L4 to the fourth wavelength light L4.

However, the present disclosure is not limited thereto, and the second wavelength conversion particle P2 may be a quantum dot QD, and the third wavelength conversion particle P3 may include phosphor. In this case, the phosphor may be K2SiF6:Mn (hereinafter referred to as KSF or a KSF fluorescent material). The phosphor KSF is characterized by exhibiting a red color having a narrow half width, which is advantageous in that the color reproduction ratio is excellent.

Referring to FIGS. 8A and 8B, according to an embodiment, the second wavelength conversion particle P2 may be smaller than the third wavelength conversion particle P3 in size. According to the quantum confinement effect, the energy band gap increases as the size of the wavelength conversion particle decreases. Therefore, the wavelength of the light emitted by the second wavelength conversion particle P2 may be shorter than the wavelength of the light emitted by the third wavelength conversion particle P3.

According to an embodiment, the light having passed through the wavelength conversion layer 30 includes the first wavelength light L1, the second wavelength light L2, the third wavelength light L3, and the fourth wavelength light L4. The light converted by the wavelength conversion layer 30 may be concentrated within a narrow range of specific wavelengths, and may have a sharp spectrum having a narrow half width. Therefore, when the color of light in such a spectrum is filtered by a color filter, color reproducibility can be improved.

Unlike the exemplary embodiment, in some embodiments, the light source 400 may further a LED that emits light of the second wavelength λ2. In this case, LEDs may be classified into and referred to as a first LED and a second LED, respectively, to distinguish from the LED 430 that emits the light of the first wavelength light λ1 that is described with respect to FIG. 6. The first LED and the second LED may be disposed adjacent to each other. For example, the first LED may be disposed in an area adjacent to one side 10s of the light guide plate 10, the second LED may be disposed adjacent to the first LED along a direction in which the side 10s of the light guide plate 10 extends, and spaced apart from the first LED.

The wavelength conversion layer 30 may further include the scattering particles 35. The scattering particles 35 may be non-quantum particles, and may be particles having no wavelength conversion capability. The scattering particles 35 scatter incident light to allow a larger amount of incident light to be applied toward the second and third wavelength conversion particles P2 and P3. In addition, the scattering particles 35 serve to uniformly control an emission angle of light for each wavelength. Specifically, when a part of incident light is applied onto the second and third wavelength conversion particles P2 and P3 to convert the wavelength of the light and then the light having the converted wavelength emitted, the scattering particles 35 have scattering characteristics that the emission direction of the light is random. If the scattering particles 35 are not present in the wavelength conversion layer 30, the third wavelength light L3 and the fourth wavelength light L4 that are emitted after colliding with the second and third wavelength conversion particles P2 and P3 may have scattering emission characteristics, but the first wavelength light L1 and the second wavelength light L2 that are emitted without colliding with the wavelength conversion particles may not have scattering emission characteristics, so that the amounts of emitted light for the first wavelength light L1, the second wavelength light L2, the third wavelength light L3, the fourth wavelength light L4 will be different with respect to the emission angle. The scattering particles 35 impart scattering emission characteristics to the first wavelength light L1 and the second wavelength light L2 that are emitted without colliding with the second and third wavelength conversion particles P2 and P3, thereby controlling the emission angle of light for each wavelength.

The scattering particles 35 may be made of any one metal oxide selected from SiO₂, TiO₂, ZnO, and SnO₂, or may be made of a combination of two or more thereof. In an embodiment, the scattering particles 35 may be made of TiO₂. TiO₂ may have at least one of an anatase crystal phase and a rutile crystal phase. Referring to FIG. 9, the scattering particles 35 may be of only the anatase crystal phase of the crystal phases of TiO₂.

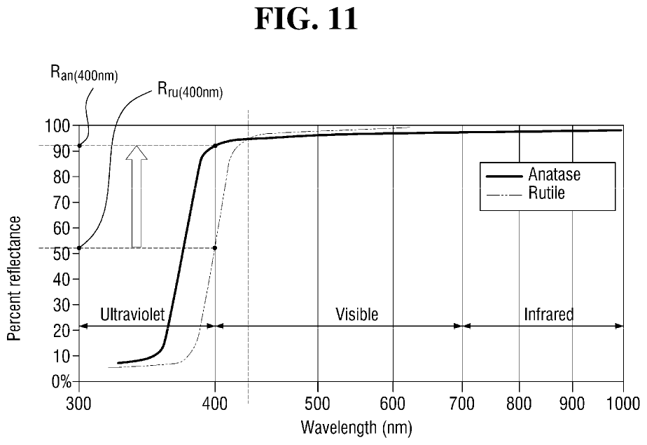

The anatase crystal phase may have higher reflectance than the rutile crystal phase in the wavelength band of the second wavelength light L2 (e.g., light having a wavelength of 370 nm to 420 nm). Therefore, when the first wavelength light L1 is used as a light source, the anatase crystal phase may have a better scattering effect than the rutile crystal phase. The related description will be provided in detail with reference to FIG. 11 showing the reflectance with respect to the crystal phase of TiO₂.

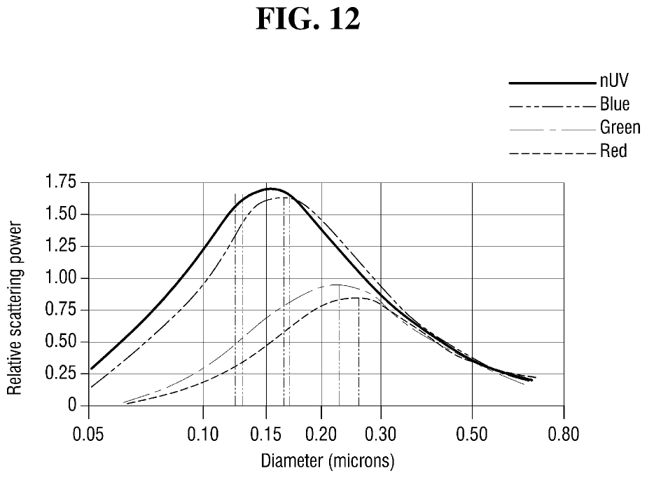

In one embodiment, the size of the scattering particle 35 may be 200 nm or less. In an exemplary embodiment, the size of the scattering particle is 100 nm to 150 nm. The related contents will be described later in detail with reference to the graph shown FIG. 12.

The volumetric ratio of the scattering particles 35 in the wavelength conversion layer 30 may be less than 5%. In an exemplary embodiment, the volumetric ratio of the scattering particles 35 may be 2% or less. When the volumetric ratio of the scattering particles 35 in the wavelength conversion layer 30 is 5% or more, the transparency of the wavelength conversion layer 30 is lowered, and thus the light extraction efficiency of the wavelength conversion layer 30 may be lowered.

Hereinafter, the characteristics of the optical member 100 according to an embodiment will be described with reference to several graphs.

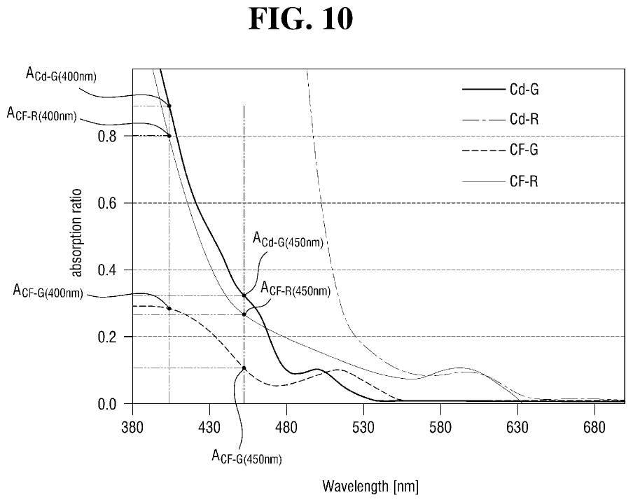

In FIG. 10, the horizontal axis represents the wavelength of the light source 400, and the vertical axis represents the absorption rates of the second wavelength conversion particles P2 and the third wavelength conversion particles P3 in accordance with the light source 400. Referring to FIG. 10, the second wavelength conversion particles P2 and the third wavelength conversion particles P3 absorb a larger amount of the first wavelength light L1 in comparison with the second wavelength light L2.

When a degree of light absorption by the second and third wavelength conversion particles P2 and P3 increases, the energy level of each of the second and third wavelength conversion particles P2 and P3 is excited by the absorbed light, and therefore the intensity of the emitted light (e.g., green light or red light) can be increased. FIG. 10 shows an exemplary case in which the second wavelength conversion particles P2 and the third wavelength conversion particles P3 are made of a cadmium (Cd) compound or an indium (In) compound.

Specifically, the light absorption rate (A_{Cd-g(450 nm)}) of the second wavelength conversion particles P2 made of a cadmium (Cd) compound at a wavelength of 450 nm has a value close to approximately 0.3, whereas the light absorption rate (A_{Cd-g(400 nm)}) thereof at a wavelength of 400 nm has a value close to approximately 0.9 or larger, so that the light absorption rate is increased by approximately three times or more. Further, the light absorption rate (A_{CF-g(450 nm)}) of the second wavelength conversion particles P2 made of an indium (In) compound at a wavelength of 450 nm has a value close to approximately 0.1, whereas the light absorption rate (A_{CF-g(400 nm)}) thereof has a value close to approximately 0.3 or higher, so that the light absorption rate is increased by approximately 3 times or more. Moreover, the light absorption rate (A_{CF-r(450 nm)}) of the third wavelength conversion particles P3 made of an indium (In) compound at a wavelength of 450 nm has a value close to approximately 0.3, whereas the light absorption rate (A_{CF-r(400 nm)}) thereof has a value close to approximately 0.8 or higher, so that the light absorption rate is increased by approximately 2.6 times or more. Although specific numerical values are not compared, FIG. 10 indicates that the light absorption rate of the third wavelength particles P3 made of a cadmium (Cd) compound at a wavelength of 400 nm is also much higher than the light absorption rate thereof at a wavelength of 450 nm.

FIG. 11 is a graph showing scattering rate of two different kinds of scattering particles with respect to a wavelength.

Referring to FIG. 11, when the first wavelength light L1 is used as a light source, the reflectance of the first wavelength light L1 varies with respect to a crystal form of the scattering particles 35. Specifically, in FIG. 11, the horizontal axis represents the intensity of wavelength of a light source, and the vertical axis represents the reflectance of the crystal phases (anatase and rutile phases) of the scattering particles 35 (in an embodiment in which the scattering particles 35 are made of TiO₂).

The anatase crystal phase may have a high reflectance at a wavelength band of about 420 nm or less as compared with the rutile crystal phase. In particular, when the anatase crystal phase is used as the scattering particles 35, the reflectance (R_{ana(400 nm)}) at a wavelength of 400 nm is about 90%. In contrast, when the rutile crystal phase is used as the scattering particles 35, the reflectance (R_{ru(400 nm}) at a wavelength of 400 nm is about 45%. Therefore, when the first wavelength light L1 is used as a light source, the reflectance of the anatase crystal phase is about two times of the reflectance of the rutile crystal phase. As the scattering particles 35 have high reflectance, the light absorption rate of the scattering particles 35 becomes relatively low, and the light scattering effect of the scattering particles 35 may be larger than that of the scattering particles 35 having low reflectance. Therefore, the scattering effect of light in the wavelength conversion layer 30 may be enhanced by the scattering particles 35 having the anatase crystal phase.

FIG. 12 is a graph showing light scattering rates of scattering particles according to a particle size.

The size (e.g., a diameter) of the scattering particle 35 may be 200 nm or less. In an exemplary embodiment, the size of the scattering particle 35 may be 100 nm to 150 nm. The maximum scattering effect of the first wavelength light L1 (e.g., near ultraviolet (nUV)) may be exhibited at a particle size of the scattering particle 35 being approximately 120 nm. As the scattering effect of the first wavelength light L1 increases, when the color of a spectrum is filtered by a color filter, color reproducibility can be improved, and the intensity of light extracted from the third wavelength light L3 and the fourth wavelength light L4 can increase.

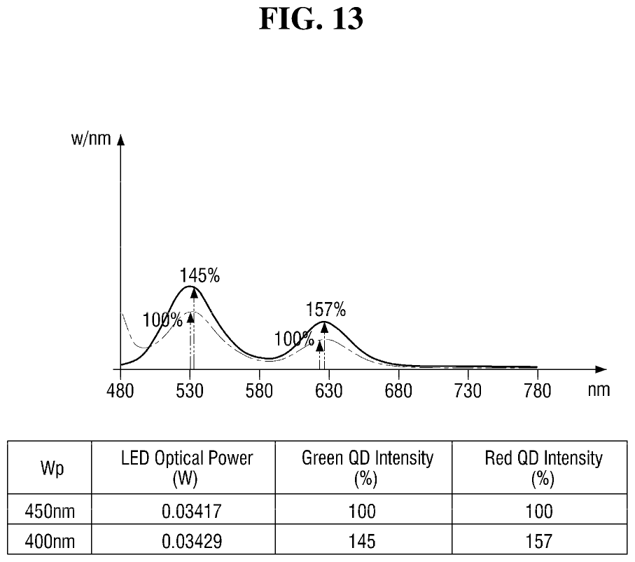

FIG. 13 is a graph showing intensity of green light and red light depending on a light source of an optical member that includes scattering particles according to an embodiment.

Referring to FIG. 13, when the anatase crystal phase is used as the scattering particles 35, and the particle size of the anatase crystal phase is approximately 200 nm, the emission amounts of the third wavelength light L3 and the fourth wavelength light L4 that are significantly different from the emission amounts of the first wavelength light L1 and the second wavelength light L2 having a slightly different output amount, can be extracted. In FIG. 13, the horizontal axis represents a wavelength of the light source, and the vertical axis represents the relative emission amounts of the third wavelength light L3 and the fourth wavelength light L4 according to the wavelength of the light source.

More specifically, in an exemplary case where the anatase crystal phase is used as the scattering particles 35, and the particle size of the anatase crystal phase is approximately 200 nm, the emission amount (Igreen(400 nm)) of the third wavelength light L3 (e.g., a green light having a wavelength of about 520 nm to 570 nm) when the first wavelength light L1 (e.g., having a wavelength 400 nm) is used as the light source is increased by about 45% as compared with the emission amount (Igreen(450 nm)) of the third wavelength light L3 when the second wavelength light L2 (e.g., having a wavelength 450 nm) is used as the light source. Similarly, the emission amount (Ired(400 nm)) of the fourth wavelength light L4 (e.g., a red light having a wavelength of about 620 nm to 670 nm) when the first wavelength light L1 is used as the light source is increased by about 57% as compared with the emission amount (Ired(450 nm)) of the fourth wavelength light L4 when the second wavelength light L2 is used as the light source.

As describe above, in the case where the first wavelength light L1 is used as the light source, the light absorption rate of the second wavelength conversion particles P2 and the third wavelength conversion particles P3 is increased as compared with the case where the second wavelength light L2 is used as the light source, so that the intensity of the third wavelength light L3 and the fourth wavelength light L4 may also be increased. However, the scattering effect exhibited by the scattering particles 35 may vary with respect to different wavelength ranges of the light source. As in the present embodiment, when the first wavelength light L1 is used as the light source, the anatase crystal type scattering particles (TiO₂) can maximize the scattering effect of incident light and/or emitted light whose wavelength is converted by the second and third wavelength conversion particles P2 and P3. As the scattering effect of the incident light (e.g., the first wavelength light L1) is maximized, scattering emission characteristics are imparted to the first wavelength light L1, and consequently the emission angle of the emitted light can be uniformly controlled. Moreover, as the scattering effect of the incident light is maximized, as described above, the intensity of emitted light (e.g., green light and red light) can be increased by a chain action/reaction.

Hereinafter, other embodiments of the optical member 100 will be described. In the following embodiments, description of the same configurations as those of the previously described embodiment may be omitted or simplified, and differences will be mainly described.

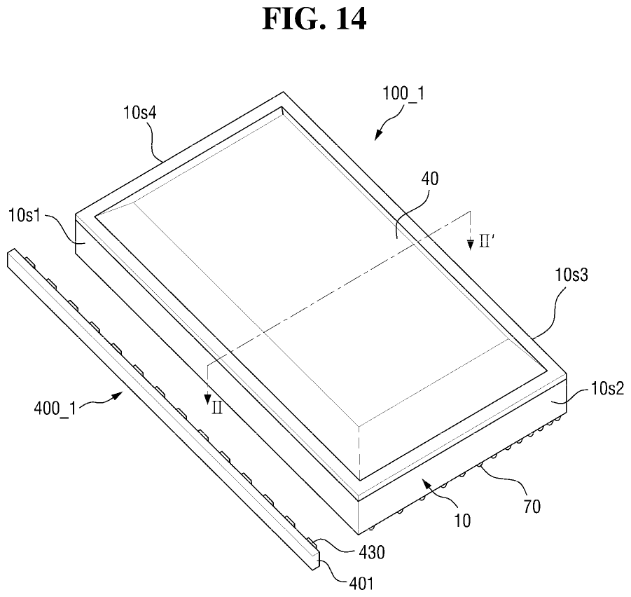

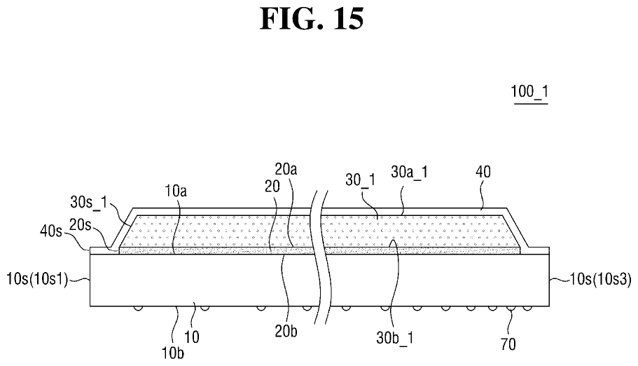

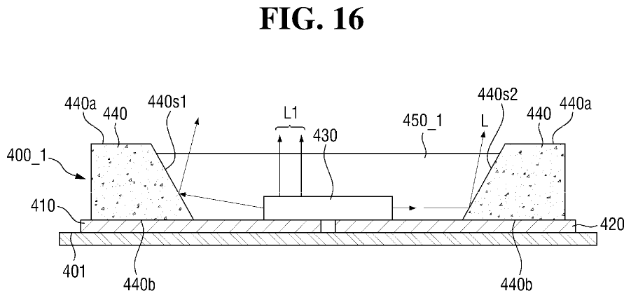

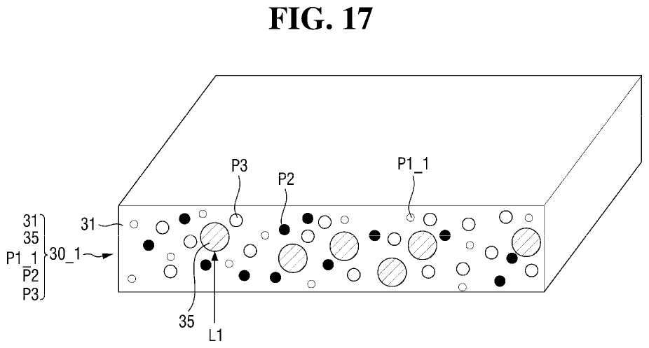

FIG. 14 is a perspective view of an optical member 100_1 and a light source 400_1 according to another embodiment, FIG. 15 is a cross-sectional view of the optical member 100_1 of FIG. 14, FIG. 16 is a cross-sectional view of the light source 400_1 of FIG. 14, and FIG. 17 is a cross-sectional view of a wavelength conversion layer 30_1 included in the optical member 100_1 of FIG. 15.

Another embodiment of FIGS. 14 to 17 is different from the aforementioned embodiment in that first wavelength conversion particles P1_1 are included in the wavelength conversion layer 30_1.

More specifically, the light source 400_1 may emit only the first wavelength light L1 because it does not include first wavelength conversion particles P1_1. Instead, the wavelength conversion layer 30_1 may include the first wavelength conversion particles P1_1 as well as the second wavelength conversion particles P2 and the third wavelength conversion particles P3, and these wavelength conversion particles P1_1, P2, and P3 are the three kinds of wavelength conversion particles converting incident light to blue wavelength light, green wavelength light, and red wavelength light. The wavelength conversion layer 30_1 may emit white light by appropriately adjusting the relative ratios of the first wavelength conversion particles P1_1, the second wavelength conversion particles P2, and the third wavelength conversion particles P3.

In the present embodiment, the first wavelength conversion particles P1_1 may absorb the first wavelength light L1 and emit the second wavelength light L2. The first wavelength conversion particle P1_1 may be, for example, a quantum dot QD, a fluorescent material, or a phosphor. When the first wavelength conversion particle P1_1 is a quantum dots QD, the size of the first wavelength conversion particle P1_1 may be smaller than the size of the second wavelength conversion particle P2 and the size of the third wavelength conversion particle P3. This is caused by a quantum confinement effect in which an energy bandgap increases as the size of the wavelength conversion particle decreases. Therefore, the wavelength of light emitted from the first wavelength conversion particle P1_1 may be shorter than the wavelength of light emitted from the second wavelength conversion particle P2 and the wavelength of light emitted the third wavelength conversion particle P3.

As described above, in the case where the first wavelength light L1 is used as the light source, the light absorption rate of the second wavelength conversion particles P2 and the third wavelength conversion particles P3 is increased as compared with the case where the second wavelength light L2 is used as the light source, so that the intensity of the third wavelength light L3 and the fourth wavelength light L4 may also be increased. However, the scattering effect exhibited by the scattering particles 35 may vary with respect to different wavelength ranges of the light source. As in the present embodiment, when the first wavelength light L1 is used as the light source, the anatase crystal type scattering particles (TiO₂) can maximize the scattering effect of incident light and/or emitted light whose wavelength is converted by the second and third wavelength conversion particles P2 and P3. As the scattering effect of the incident light (e.g., the first wavelength light L1) is maximized, scattering emission characteristics are imparted to the first wavelength light L1, and consequently the emission angle of the emitted light can be uniformly controlled. Moreover, as the scattering effect of the incident light is maximized, as described above, the intensity of emitted light (e.g., green light and red light) can be increased by a chain action/reaction.

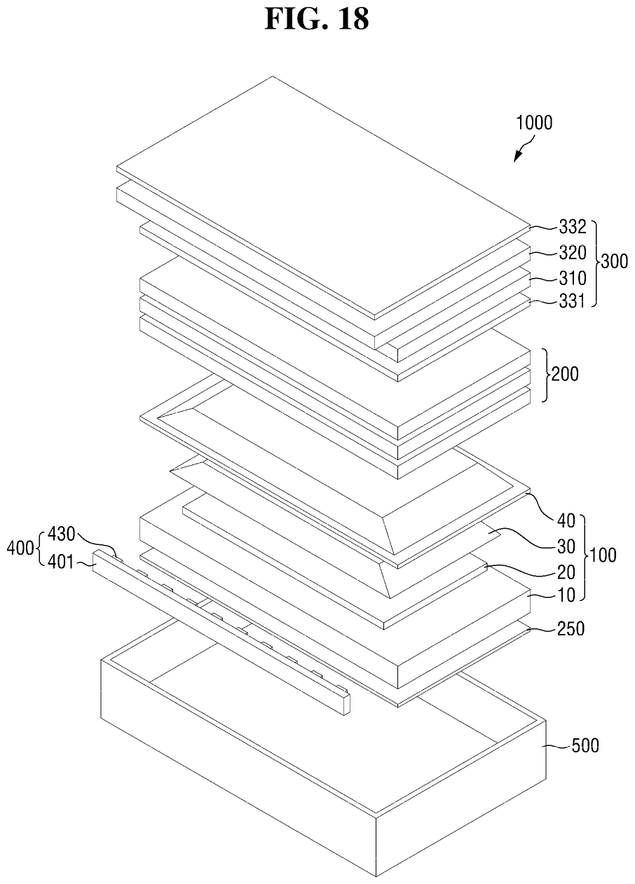

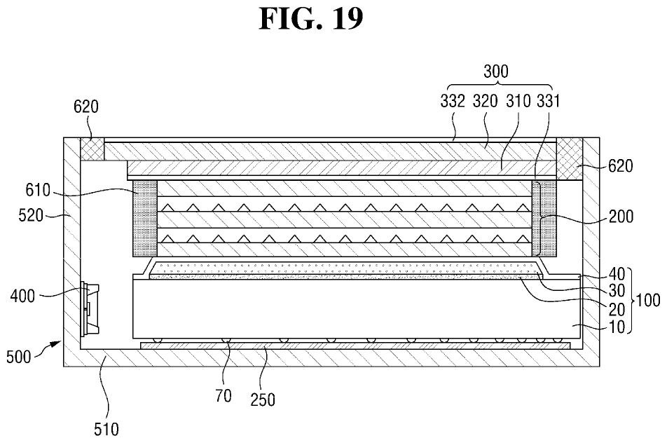

FIG. 18 is an exploded perspective view of a display device 1000 including a modified light guide plate according to another embodiment, and FIG. 19 is a cross-sectional view of the display device 1000 of FIG. 18.

Referring to FIGS. 18 and 19, a display device 1000 includes a light source 400, an optical member 100 disposed in an emission path of the light source 400, and a display panel 300 disposed over the optical member 100.

The light source 400 is disposed on one side of the optical member 100. The light source 400 may be disposed adjacent to the light incidence surface 10s1 of the light guide plate 10 of the optical member 100. The light source 400 may include a plurality of point light sources or a plurality of line light sources. The point light source may be an

LED light source. As the LED light source, a plurality of LEDs 430 may be mounted on a printed circuit board 401. The LED 430 may emit the first wavelength light L1 and the second wavelength light L2.

In an embodiment, the LED 430 may be a top-emission type LED that emits light to a top surface. In this case, the printed circuit board 401 may be disposed on a side wall 520 of a housing 500. However, the present disclosure is not limited thereto, and the LED 430 may be a side-emission type LED that emits light to a side surface. In this case, the printed circuit board 401 may be disposed on a bottom surface 510 of the housing 500.

The first wavelength light L1 and the second wavelength light L2 emitted from the LED 430 are incident on the light guide plate 10 of the optical member 100. The light guide plate 10 of the optical member 100 guides light and outputs the light through the upper surface 10a or the lower surface 10b of the light guide plate 10. The wavelength conversion layer 30 of the optical member 100 converts a part of the first wavelength light L1 and the second wavelength light L2 incident from the light guide plate 10 to light of different wavelengths such as the third wavelength light L3 and the fourth wavelength light L4. The third wavelength light L3 and the fourth wavelength light L4 are emitted upwardly together with the first wavelength light L1 and the second wavelength light L2, and are provided toward the display panel 300.

The display device 1000 may further include a reflection member 250 disposed under the optical member 100. The reflection member 250 may include a reflective film or a reflective coating layer. The reflection member 250 reflects the light that is emitted from the lower surface 10b of the light guide plate 10 of the optical member 100 and guides the reflected light into the light guide plate 10 again.

The display panel 300 is disposed over the optical member 100. The display panel 300 receives light from the optical member 100 to display an image on a screen. Examples of the display panel 300 that displays an image on the screen include a liquid crystal display (LCD) panel and an electrophoretic panel. Hereinafter, a liquid crystal display panel is exemplified as the display panel 300, but various other types of light-receiving display panels may be applied without departing from the scope and sprit of the present disclosure.

The display panel 300 includes a first substrate 310, a second substrate 320 facing the first substrate 310, and a liquid crystal layer (not shown) disposed between the first substrate 310 and the second substrate 320. The first substrate 310 and the second substrate 320 overlap each other. In an embodiment, any one of the first and second substrates 310 and 320 may be larger than the other substrate and thus may protrude outwardly from the other substrate. It is shown in FIGS. 18 and 19 that the second substrate 320 is larger than the first substrate 310 and protrudes from a side surface on which the light source 400 is disposed. The protruding region of the second substrate 320 may provide a space for mounting a driving chip or an external circuit board. Unlike the exemplified embodiment, the first substrate 310 may be larger than the second substrate 320, and may protrude outwardly from the second substrate 320. The region where the first substrate 310 and the second substrate 320 overlap each other in the display panel 300 except for the protruding region may be substantially aligned with the side surface 10s of the light guide plate 10 of the optical member 100.

The display panel 300 may further include a first polarizing member 331 and a second polarizing member 332 respectively disposed on a lower surface of the first substrate 310 in the thickness direction and an upper surface of the second substrate 320 in the thickness direction. Each of the first polarizing member 331 and the second polarizing member 332 may include a polyvinyl alcohol polarizer, and may be in the form of a film. The first polarizing member 331 and the second polarizing member 332 may be disposed such that their polarization axes are orthogonal to each other. The first polarizing member 331 may polarize the light provided through the optical member 100 and allow the light polarized in one direction to enter the display panel 300. The second polarizing member 332 may polarize the light emitted from the display panel 300 and provide the polarized light to a user's eye to display an image.

Referring to FIG. 19, the optical member 100 may be coupled with the display panel 300 through an intermodule coupling member 610. The intermodule coupling member 610 may have a rectangular frame shape in a plan view. The intermodule coupling member 610 may be disposed at the edges of the display panel 300 and the optical member 100, respectively.

In an embodiment, the lower surface of the intermodule coupling member 610 is disposed on the upper surface of the passivation layer 40 of the optical member 100. The intermodule coupling member 610 may be disposed on the passivation layer 40 such that its lower surface overlaps only the upper surface 30a of the wavelength conversion layer 30 and do not overlap the side surfaces 30s of the wavelength conversion layer 30.

The intermodule coupling member 610 may include a polymer resin or an adhesive tape.

The display device 1000 may further include the housing 500. One side of the housing 500 is open, and the housing 500 includes the bottom surface 510 and the side wall 520 connected to the bottom surface 510. The light source 400, an assembly including the optical member 100 and the display panel 300, and the reflection member 250 may be accommodated in a space defined by the bottom surface 510 and the side wall 520. The light source 400, the reflection member 250, and the assembly of the optical member 100 and the display panel 300 are disposed on the bottom surface 510 of the housing 500. The display panel 300 may be disposed adjacent to an upper end of the side wall 520 of the housing 500, and they may be coupled to each other by a housing coupling member 620. The housing coupling member 620 may be formed in a rectangular box shape. The housing coupling member 620 may include a polymer resin or an adhesive tape.

The display device 1000 may further include at least one optical film 200. The optical film 200 may be accommodated in a space surrounded by the intermodule coupling member 610 between the optical member 100 and the display panel 300. The side surfaces of the optical film 200 may be in contact with inner side surfaces of the intermodule coupling member 610 to be attached thereto. Although it is shown in FIG. 18 that the optical film 200 and the optical member 100 are spaced apart from each other, and the optical member 200 and the display panel 300 are spaced apart from each other, the spaces therebetween may not be necessarily required.

In the present embodiment, the optical film 200 may be an optical film in which two prism films are laminated and a luminance enhancing film is formed on the laminate. However, the present disclosure is not limited thereto, and the display device 1000 may include a plurality of optical films 200 of the same kind or different kinds. For example, a laminate structure may be formed by various combinations of films selected from a prism film, a diffusion film, a microlens film, a lenticular film, a polarizing film, a reflective polarizing film, a phase retardation film, and a luminance enhancing film. When the plurality of optical films 200 are applied, the respective optical films 200 may be arranged to overlap each other, and the respective side surfaces may be in contact with the inner surface of the intermodule coupling member 610 to be attached thereto. The respective optical films 200 may be spaced apart from each other, and an air layer may be disposed therebetween.

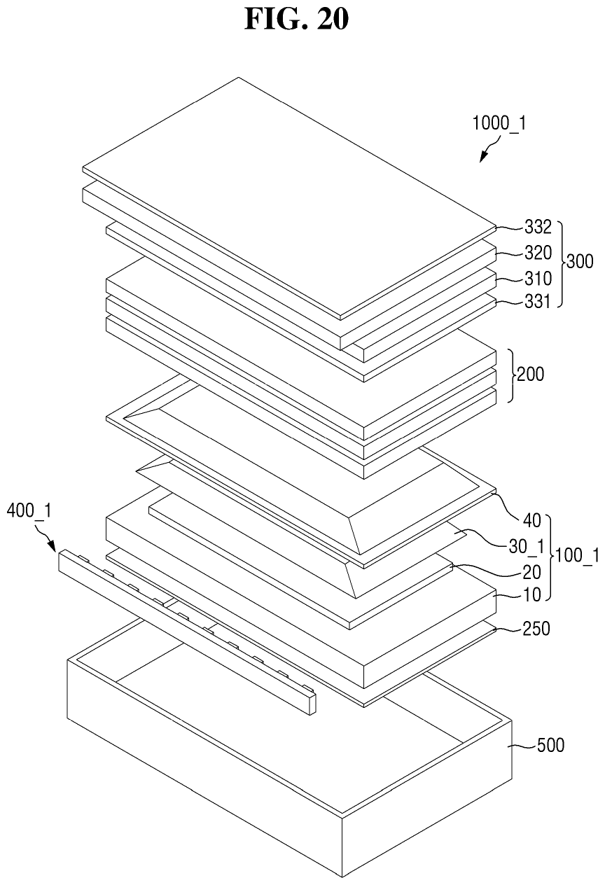

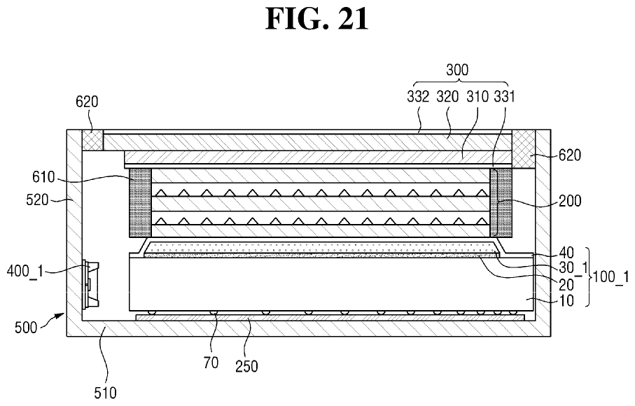

FIG. 20 is an exploded perspective view of a display device 1000_1 according to another embodiment, and FIG. 21 is a cross-sectional view of the display device 1000_1 of

FIG. 20.

The configuration of the display device 1000_1 of FIGS. 20 and 21 is the same as the configuration of the display device 1000 of FIGS. 18 and 19 except that the display device 1000_1 includes the optical member 100_1 and the light source 400_1 of FIGS. 14 to 16. Since the optical member 100_1 and the light source 400_1 have been described above with respect to FIGS. 14 to 16, the description of the optical member 100_1 and the light source 400_1 will not be repeated. Since the other components except for the optical member 100_1 and the light source 400_1 according to the present embodiment are substantially the same as those described with reference to FIGS. 15 and 16, and a description thereof will be omitted.

As describe above, in the case where the first wavelength light L1 is used as the light source, the light absorption rate of the second wavelength conversion particles P2 and the third wavelength conversion particles P3 is increased as compared with the case where the second wavelength light L2 is used as the light source, so that the intensity of the third wavelength light L3 and the fourth wavelength light L4 may also be increased. However, the scattering effect exhibited by the scattering particles 35 may vary with respect to different wavelength ranges of the light source. As in the present embodiment, when the first wavelength light L1 is used as the light source, the anatase crystal type scattering particles (TiO₂) can maximize the scattering effect of incident light and/or emitted light whose wavelength is converted by the second and third wavelength conversion particles P2 and P3. As the scattering effect of the incident light (e.g., the first wavelength light L1) is maximized, scattering emission characteristics are imparted to the first wavelength light L1, and consequently the emission angle of the emitted light can be uniformly controlled. Moreover, as the scattering effect of the incident light is maximized, as described above, the intensity of emitted light (e.g., green light and red light) can be increased by a chain action/reaction.

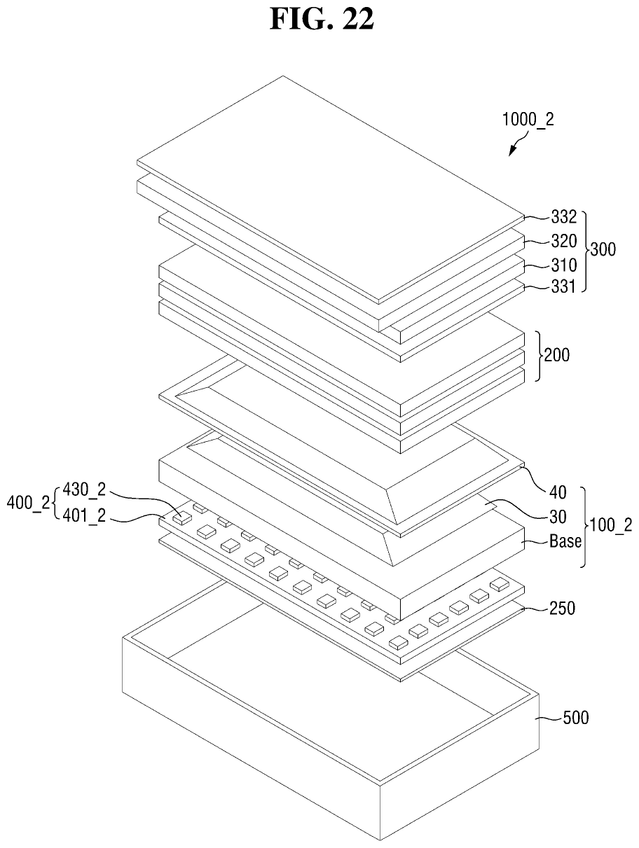

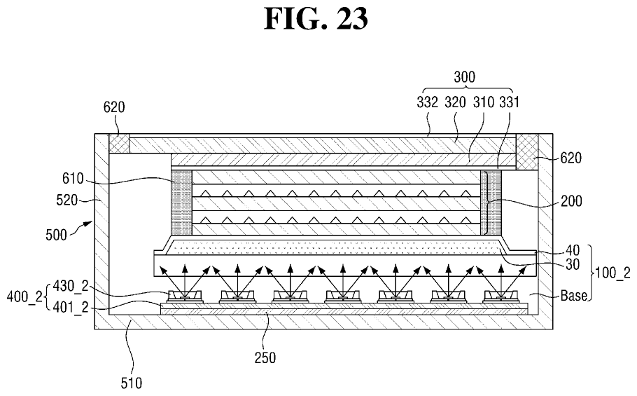

FIG. 22 is an exploded perspective view of a display device 1000_2 according to still another embodiment, and FIG. 23 is a cross-sectional view of the display device 1000_2 of FIG. 22.

The display device 1000_2 according to FIGS. 22 and 23 is different from the display device 1000 of FIGS. 18 and 19 in that an optical member 100_2 of the display device 1000_2 includes a support member base, the wavelength conversion layer 30 disposed on the supporting member base, and the passivation layer 40 disposed on the wavelength conversion layer 30 without the light guide plate 10 and the low refractive layer 20, and a light source 400_2 is disposed under the display panel 300.

More specifically, the display device 1000_2 may include a reflection member 250, the light source 400_2 that is disposed on the reflection member 250, the optical member 100_2 disposed on the light source 400_2, and the display panel 300 disposed on the optical member 100_2. A printed circuit board 401_2 for mounting the light source 400_2 may be disposed in a substantially flat shape over the entire surface of the reflection member 250. The planar size of the printed circuit board 401_2 may be equal to the planar size of the reflection member 250, but the present disclosure is not limited thereto, and may be smaller or larger than the planar size of the reflection member 250. A plurality of LEDs 430_2 may be disposed on the printed circuit board 401_2. In the present embodiment, the LED 430_2, as shown in FIGS. 22 and 23, may be a top-emission type LED that emits light to a top surface. The support member base for supporting the wavelength conversion layer 30 may be disposed on the light source 400_2. The support member base may support the wavelength conversion layer 30. The planar shape of the support member base may be a rectangular shape, but is not limited thereto. In an exemplary embodiment, the support member base may have a rectangular planar shape with a uniform thickness. The support member base may be made of an inorganic material, but the present disclosure is not limited thereto. The wavelength conversion layer 30 and the passivation layer 40 for covering the wavelength conversion layer 30 to protect the wavelength conversion layer 30 from external oxygen and moisture may be disposed on the support member base. The display panel 300 may be disposed on the passivation layer 40. The display device 1000_2 may further include at least one optical film 200. The optical film 200 may be accommodated in a space surrounded by the intermodule coupling member 610 between the optical member 100_2 and the display panel 300. For example, a laminate structure may be formed by various combinations of films selected from a prism film, a diffusion film, a microlens film, a lenticular film, a polarizing film, a reflective polarizing film, a phase retardation film, and a luminance enhancing film.

As describe above, in the case where the first wavelength light L1 is used as the light source, the light absorption rate of the second wavelength conversion particles P2 and the third wavelength conversion particles P3 is increased as compared with the case where the second wavelength light L2 is used as the light source, so that the intensity of the third wavelength light L3 and the fourth wavelength light L4 may also be increased. However, the scattering effect exhibited by the scattering particles 35 may vary with respect to different wavelength ranges of the light source. As in the present embodiment, when the first wavelength light L1 is used as the light source, the anatase crystal type scattering particles (TiO₂) can maximize the scattering effect of incident light and/or emitted light whose wavelength is converted by the second and third wavelength conversion particles P2 and P3. As the scattering effect of the incident light (e.g., the first wavelength light L1) is maximized, scattering emission characteristics are imparted to the first wavelength light L1, and consequently the emission angle of the emitted light can be uniformly controlled. Moreover, as the scattering effect of the incident light is maximized, as described above, the intensity of emitted light (e.g., green light and red light) can be increased by a chain action/reaction.

As described above, according to embodiments of the present disclosure, each of a backlight assembly, a display device, and an optical member can perform both light guiding and wavelength conversion as an integrated single member. In particular, the integrated single member is optimized for efficient extracting light from a near ultraviolet (nUV) light source.

The effects of the present disclosure are not limited by the foregoing, and other various effects are anticipated herein.

Although the preferred embodiments of the present disclosure have been disclosed for illustrative purposes, those skilled in the art will appreciate that various modifications, additions, and substitutions are possible, without departing from the scope and spirit of the present disclosure and the accompanying claims.

What is claimed is:

1. A backlight assembly comprising:
an optical member including a light guide plate and a wavelength conversion layer that is disposed on the light guide plate; and
a light source disposed on one side of the light guide plate,
wherein the wavelength conversion layer includes scattering particles having a particle size of 200 nm or less, and the scattering particles are of an anatase crystal type of titanium dioxide (TiO₂).

2. The backlight assembly of claim 1,
wherein the light source provides first light of a first wavelength to the light guide plate, and the light conversion layer includes first wavelength conversion particles that convert the first light of the first wavelength to light of a second wavelength and second wavelength conversion particles that convert the first light of the first wavelength to light of a third wavelength.

3. The backlight assembly of claim 2,
wherein the light source provides second light of a fourth wavelength that is different from the first wavelength to the light guide plate, the first wavelength conversion particles convert the second light to the light of the second wavelength, and the second wavelength conversion particles convert the second light to the light of the third wavelength.

4. The backlight assembly of claim 3,
wherein the first wavelength and the fourth wavelength are within a wavelength range of blue light or near ultraviolet light.

5. The backlight assembly of claim 4,
wherein the first wavelength is 320 nm to 420 nm, and the fourth wavelength is 420 nm to 470 nm.

6. The backlight assembly of claim 4,
wherein the light source includes a light emitting element that emits the first light and third wavelength conversion particles that convert the first light of the first wavelength to the second light of the fourth wavelength.

7. The backlight assembly of claim 2,
wherein the second wavelength is within a wavelength range of green light, and the third wavelength is within a wavelength range of red light.

8. The backlight assembly of claim 7,
wherein the first wavelength conversion particles include quantum dots, and the second wavelength conversion particles include a KSF fluorescent material.

9. The backlight assembly of claim 2,
wherein the wavelength conversion layer further includes third wavelength conversion particles that convert the first light to second light of a fourth wavelength.

10. The backlight assembly of claim 9,
wherein the first wavelength conversion particles convert the second light of the fourth wavelength to the light of the second wavelength, and the second wavelength conversion particles convert the second light of the fourth wavelength to light of the third wavelength.

11. The backlight assembly of claim 1,
wherein a volumetric ratio of the scattering particles in the wavelength conversion layer is less than 5%.

12. The backlight assembly of claim 11,
wherein a reflectance of the scattering particles to light of a wavelength of 400 nm is 80% or more.

13. The backlight assembly of claim 1,
wherein the optical member further includes a low refractive layer disposed between the light guide plate and the wavelength conversion layer, and
the light guide plate, the low refractive layer, and the wavelength conversion layer are integrally coupled with each other.

14. The backlight assembly of claim 13, further comprising:
a passivation layer covering the wavelength conversion layer and the low refractive layer.

15. The backlight assembly of claim 1,
wherein the light guide plate includes glass.

16. A display device, comprising:
a backlight assembly including an optical member that includes a light guide plate and a wavelength conversion layer that is disposed on the light guide plate, and a light source disposed on one side of the light guide plate; and
a display panel disposed over the backlight assembly,
wherein the wavelength conversion layer includes scattering particles having a particle size of 200 nm or less, and the scattering particles are of an anatase crystal type of titanium dioxide (TiO₂).

17. The display device of claim 16,
wherein the light source provides first light of a first wavelength to the light guide plate, and
the light conversion layer includes first wavelength conversion particles that convert the first light of the first wavelength to light of a second wavelength and second wavelength conversion particles that convert the first light of the first wavelength to light of a third wavelength.

18. An optical member, comprising:
first wavelength conversion particles that convert first light of a first wavelength to light of a second wavelength;
second wavelength conversion particles that convert the first light of the first wavelength to light of a third wavelength; and
a wavelength conversion layer including scattering particles having a particle size of 200 nm or less,
wherein the scattering particles are of an anatase crystal type of titanium dioxide (TiO₂).

19. The optical member of claim 18, further comprising:
a low refractive layer disposed under the wavelength conversion layer; and
a light guide plate disposed under the low refractive layer and including glass,
wherein the light guide plate, the low refractive layer, and the wavelength conversion layer are integrally coupled with each other.

20. The optical member of claim 19,
wherein the wavelength conversion layer further includes third wavelength conversion particles that convert the first light of the first wavelength to second light of a fourth wavelength, and
the first wavelength conversion particles convert the second light of the fourth wavelength to the light of the second wavelength, and the second wavelength conversion particles convert the second light of the fourth wavelength to the light of the third wavelength.
